(19) United States
(12) Patent Application Publication
(10) Pub. No.: US 2020/0075806 A1
(43) Pub. Date: Mar. 5, 2020

(54) PATTERNED SUBSTRATE FOR LIGHT EMITTING DIODE

(71) Applicant: Good Mass International Co., Ltd., Hsinchu Ctiy (TW)

(72) Inventors: Jih-Cheng Yang, Hsinchu City (TW); R-Hau Yang, Hsinchu City (TW)

(21) Appl. No.: 16/116,846

(22) Filed: Aug. 29, 2018

(51) Int. Cl. H01L 33/20

(52) U.S. Cl. CPC H01L 33/20; H01L 2933/0091

(57) ABSTRACT

This invention relates to a patterned substrate for light emitting diodes. The patterned substrate includes a surface having a plurality of cones, wherein each cones includes three smooth conical surfaces and three rough surfaces. The smooth conical surfaces and the rough surfaces are alternately arranged with respect to each other.

### CROSS REFERENCE TO RELATED APPLICATIONS

Pursuant to 37 C. F. R. § 1.78(a)(4), this application is related to Taiwanese Patent Application No. 106110053, filed on Mar. 27, 2017, which is expressly incorporated by reference in its entirety.

### BACKGROUND OF THE INVENTION

### Technical Field

The present invention relates to a patterned substrate for light emitting diodes.

### Description of the Prior Art

Light emitting diodes are commonly used in various kinds of daily life products and applications such as illuminations, signal indicators, displays, computers, etc. Light emitting diodes transform electricity into light through combination of electrons and holes. Due to a unique property of luminescene, light emitting diodes have many advantages such as energy saving, fast response, no idling time needed, long life time, etc. Moreover, light emitting diode are small in volume, have good impact resistance, and may be mass produced by semiconductor manufacturing processes, so it is easy to fabricate small-sized or array-type devices depending on demands.

In recent years, energy issues have grown worse and worse and the whole world has endeavored to achieve energy saving and carbon reduction, so it is a goal for industries to promote light extraction efficiency of light emitting diodes. In a perfect light emitting diode, the light generated by combination of electrons and holes may completely radiate to an external environment, achieving a light extraction efficiency of 100%. However, in fact, the internal structure and materials of a light emitting diode may cause various light propagation loss, thus light cannot completely radiate to an external environment and light extraction efficiency is reduced.

As described in the Taiwanese Patent Application No. 104126193 (hereinafter referred to as Prior Art 1), in order to promote light extraction efficiency of a light emitting diode, industries have already developed a substrate composed of one or more protrusive structures each having multiple protrusive points so as to provide more scattering surfaces. In this way, the substrate can help the light generated by the light emitting diode to radiate to an external environment. However, since the bumps only exist in the first regions of the lower portions of the protrusive structures, its light extraction efficiency can be further improved.

Moreover, U.S. Patent Publication No. 2014/0,367,693 A1 (hereinafter referred to as Prior Art 2) has developed a substrate with multiple protrusive structures each having multiple protrusive points. However, a high proportion of the surface area of the substrate of Prior Art 2 is covered with protrusive points so it's difficult to perform epitaxial growth. Therefore, it is difficult to get good quality epitaxial growth. Consequently, its light extraction efficiency can be further improved.

### SUMMARY OF THE INVENTION

In view of this, a patterned substrate for light emitting diodes is provided according to one aspect of the present invention. The patterned substrate includes a surface having a plurality of cones, wherein each cone includes three smooth conical surfaces and three rough surfaces alternatively arranged with respect to each other. In one embodiment, each rough surface comprises an upper portion and a lower portion, wherein each upper portion has a first base angle ranging from about 51 degrees to about 70 degrees and each lower portion has a second base angle ranging from about 30 degrees to about 50 degrees. In another embodiment, the arithmetic mean roughness (Ra) of each rough surface ranges from about 10 nanometer (nm) to about 300 nm. In yet another embodiment, the diameter of the base of the cone ranges from about 0.2 micron meter (μm) to about 5 μm and the height of the cone ranges from about 0.1 μm to about 2 μm, wherein the ratio of “the diameter of the base” to “the height” ranges from about 0.02 to about 10. In yet another embodiment, when viewed from the top of the cone, one of the rough surfaces of three adjacent cones falls in an area defined by the three apexes of the three adjacent cones.

In another aspect of the present invention, a patterned substrate for light emitting diodes is provided. The patterned substrate includes a surface having a plurality of cones, wherein each cone includes three smooth conical surfaces and three concave surfaces alternatively arranged with respect to each other. Each concave surface comprises an upper portion and a lower portion, wherein each upper portion has a first base angle ranging from about 51 degrees to about 70 degrees and each lower portion has a second base angle ranging from about 30 degrees to about 50 degrees. In one embodiment, the diameter of the base of the cone ranges from about 0.2 μm to about 5 μm and the height of the cone ranges from about 0.1 μm to about 2 μm, wherein the ratio of “the diameter of the base” to “the height” ranges from about 0.02 to about 10. In another embodiment, when viewed from the top of the cone, one of the concave surfaces of three adjacent cones falls in an area defined by the three apexes of the three adjacent cones.

Other aspects and advantages of the present invention will become apparent from the following detailed description in conjunction with the accompanying drawings.

### BRIEF DESCRIPTION OF THE DRAWINGS

The drawings are exemplary and illustrative and the present inventions are not limited by the drawings. In the drawings, similar or the same components are designated by the same numerals.

FIG. 1 illustrates a cross-sectional view of a patterned substrate for light emitting diodes.

FIG. 2(a) is a schematic top view of a cone of a patterned substrate for light emitting diodes according to one embodiment of the present invention.

FIG. 2(b) is an enlarged view of a rough surface of the cone as shown in FIG. 2(a).

FIG. 3(a) is a schematic top view of a cone of a patterned substrate for light emitting diodes according to another embodiment of the present invention.

FIG. 3(b) is another schematic top view of the cone of a patterned substrate for light emitting diodes according to another embodiment of the present invention.

FIG. 4(a) is a schematic top view of a cone of a patterned substrate for light emitting diodes according to another embodiment of the present invention.

FIG. 4(b) is a cross-sectional view of the cone as shown in FIG. 4(a) taken along the line AA′.

FIG. 5(a) is a top view of a portion of the patterned substrate for light emitting diodes as shown in FIG. 1 according to one embodiment of the present invention.

FIG. 5(b) is another top view of the portion of the patterned substrate for light emitting diodes as shown in FIG. 1 according to one embodiment of the present invention.

FIG. 6 is a scanning electron microscope (SEM) top view of the cone as shown in FIG. 2(a).

FIG. 7 is a SEM top view of a portion of a patterned substrate for light emitting diodes.

### DETAILED DESCRIPTION OF THE PREFERRED EMBODIMENTS

Hereinafter several preferred embodiments are described in detail in conjunction with the companying figures in order to provide a thorough understanding of the present invention. In the following description, many specific details are provided. However, to a person of ordinary skills in the art, the present invention may be practiced without some or all of these specific details. In other instances, well-known process operations and/or structures have not been described in detail to not unnecessarily obscure the present invention. While the disclosed embodiments will be described in conjunction with the specific embodiments, it will be understood that it is not intended to limit the disclosed embodiments.

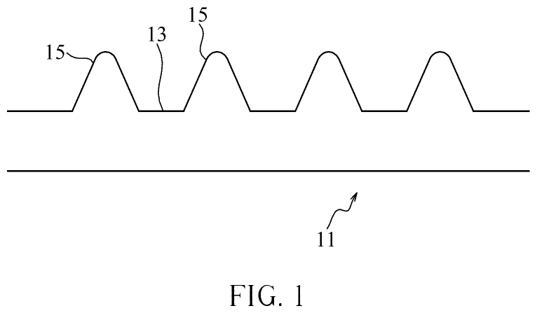

FIG. 1 illustrates a cross-sectional view of a patterned substrate for light emitting diodes. In the present invention, the patterned substrate for light emitting diodes for example may be a sapphire substrate or a silicon substrate, but is not limited thereto. As shown in FIG. 1, the patterned substrate 11 comprises a surface 13 having a plurality of cones 15. In one embodiment of the present invention, a substrate surface 13 sandwiched between two adjacent cones 15 may be a flat surface so as to provide an initial surface configured for a subsequent epitaxial growth for forming the light emitting diode.

In the present invention, the diameter of the base of each cone ranges from about 0.2 micron meter (μm) to about 5 μm and the height of each cone ranges from about 0.1 μm to about 2 μm, wherein the ratio of “the diameter of the base” to “the height” ranges from about 0.02 to about 10, but not limited thereto. However, excessive height may cause difficulties in subsequent epitaxial growth. The height is defined by the distance between the base of a cone and the apex of this cone.

Various embodiments of the cone shown in FIG. 1 are explained in detail in the following descriptions.

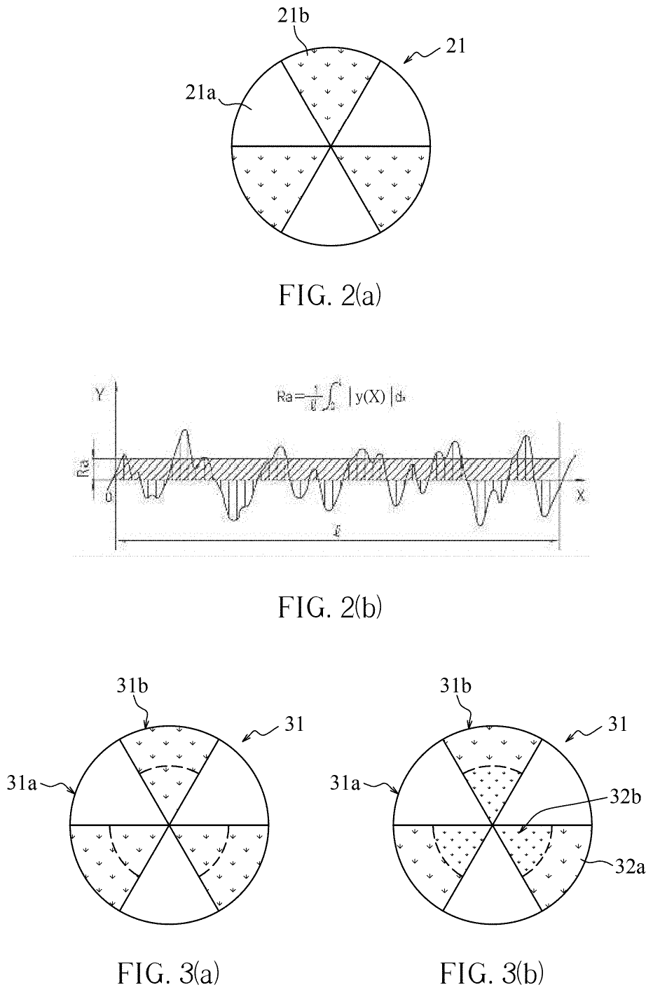

FIG. 2(a) is a schematic top view of a cone 21 of a patterned substrate for light emitting diodes according to one embodiment of the present invention. As shown in FIG. 2(a), the cone 21 may comprise three smooth conical surfaces 21a and three rough surfaces 21b and the smooth conical surfaces 21a and the rough surfaces 21b are alternatively arranged with respect to one another.

Specifically, the cone 21 is derived by chemically etching the surface of a cone. During the etching process, only three surfaces are etched and become rough surfaces (i.e. the rough surfaces 21b) while the other three surfaces are not etched and remain smooth conical surfaces (i.e. the smooth conical surfaces 21a).

FIG. 2(b) is an enlarged view of a rough surface of the cone 21 as shown in FIG. 2(a). As shown in FIG. 2(b), the rough surface has an arithmetic mean roughness Ra. Please refer to equation (f). The Ra herein means the arithmetic mean of the absolutes of the vertical deviations (y(x)) within sampling length l.

$${R}_{a} = \frac{1}{l} {\int }_{0}^{l} \vert y ( x ) \vert dx \qquad ( f )$$

In the present invention, the arithmetic mean roughness Ra of a rough surface may range from about 10 nanometer (nm) to about 300 nm, but not limited thereto.

It is generally believed that a rough surface may provide more scattering surfaces, thereby helping the light generated by a light emitting diode to radiate to an external environment so as to improve the light extraction efficiency of the light emitting diode. Furthermore, the arrangement that the smooth conical surfaces and the rough surfaces being alternatively disposed can improve epitaxial growth quality so as to further improve the overall epitaxy quality and the light extraction efficiency of the light emitting diodes. Compared to the rough surface as shown in FIG. 2(a), Prior Art 1 (the protrusive points are only arranged in the first region of the lower portion) has a smaller ratio of the area of the rough surface to the area of the smooth surface; Prior Art 2 does not have alternative arrangement. Therefore, the patterned substrate comprising the rough surfaces such as the ones shown in FIG. 2(a) are superior to the patterned substrates derived by Prior Art 1 and Prior Art 2.

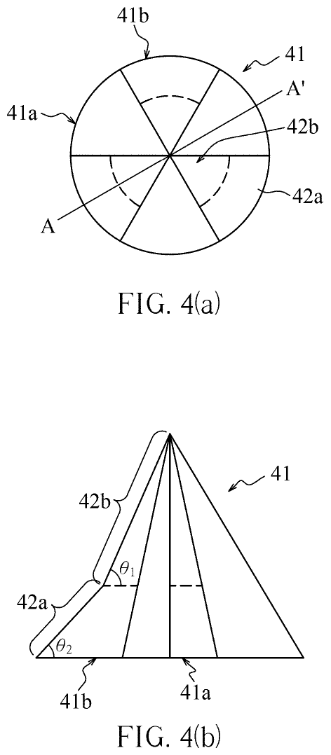

FIG. 3(a) is a schematic top view of a cone 31 of a patterned substrate for light emitting diodes according to another embodiment of the present invention. The cone 31 of FIG. 3(a) is a modification of the cone 21 of FIG. 2(a). The cone 31 comprises three smooth conical surfaces 31a and three rough surfaces 31b and the smooth conical surfaces 31a and the rough surfaces 31b are alternatively arranged with respect to one another. The differences between the cone 31 and the cone 21 are that: each rough surface 31b of the cone 31 is a concave surface and each concave surface includes a lower portion and an upper portion, wherein the base angle of each upper portion is greater than the base angle of each lower portion (the concave surface will be further described with reference to FIG. 4(b)).

FIG. 3(b) is another schematic top view of the cone 31 of a patterned substrate for light emitting diodes according to another embodiment of the present invention. As shown in FIG. 3(b), each rough surface 31b of the cone 31 includes a lower portion 32a and an upper portion 32b, wherein the base angle of each upper portion 32b is greater than the base angle of each lower portion 32a. To illustrate the difference easily, the Ra(s) of the lower portion 32a and the upper portion 32b are shown to be considerably different. However, it is to be understood that Ra is a function of the location. Specifically, Ra becomes bigger and bigger as the location approaches the apex of the cone 31.

FIG. 4(a) is a schematic top view of a cone 41 of a patterned substrate for light emitting diodes according to another embodiment of the present invention. FIG. 4(b) is a cross-sectional view of the cone as shown in FIG. 4(a) taken along the line AA′. As shown in FIGS. 4(a) and 4(b), the cone 41 includes three smooth conical surfaces 41a and three concave surfaces 41b and the smooth conical surfaces 41a and the concave surfaces 41b being alternatively arranged with respect to one another. When viewed from a side, each concave surface 41b is generally a triangle with a concave edge. More specifically, as shown in FIG. 4(b), each concave surface 41b comprises a lower portion 42a with a second base angle θ2 and an upper portion 42b with a first base angle θ1. The first base angle θ1 is greater than the second base angle θ2. For example, the first base angle θ1 ranges from about 51 degrees to about 70 degrees and the second base angle θ2 ranges from about 30 degrees to about 50 degrees.

It is generally believed that a small included angle between the cone and the substrate (for example the second base angle θ2 ranging from about 30 degrees to about 50 degrees as shown in FIG. 4(b)) will help the epitaxial growth quality so as to improve the light extraction efficiency of the light emitting diode.

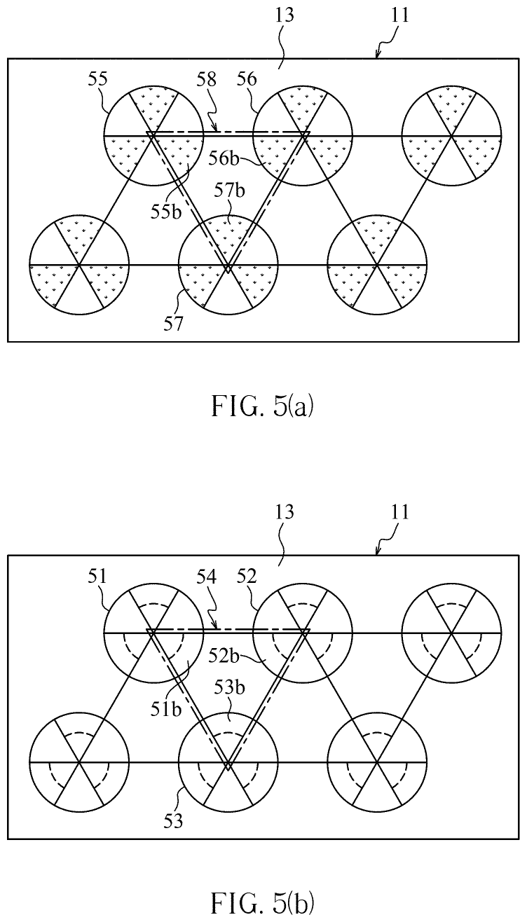

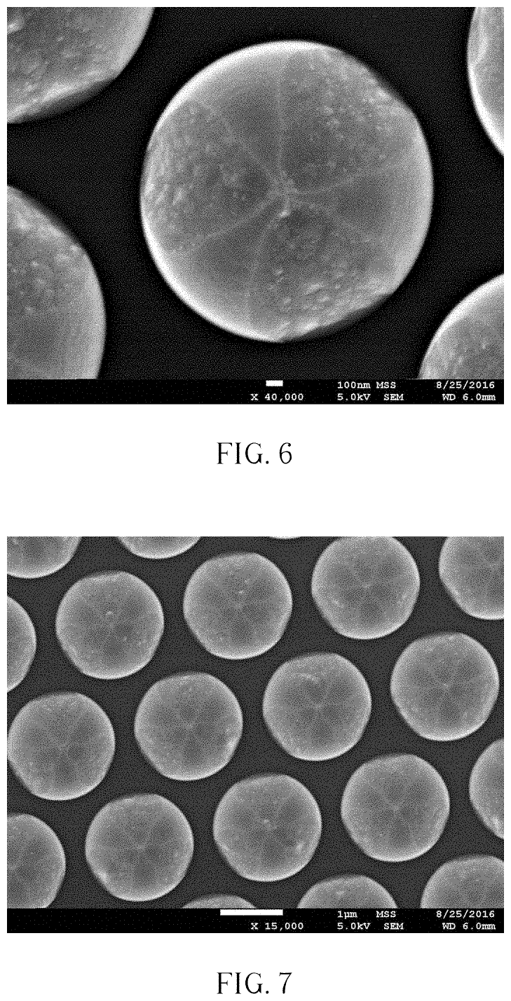

FIG. 5(a) is a top view of a portion of the patterned substrate 11 for light emitting diode as shown in FIG. 1 according to one embodiment of the present invention. As shown in FIG. 5(a), the patterned substrate 11 comprises a surface 13 having a plurality of cones formed by chemically etching process (for example, the cone 21 as shown in FIG. 2(a)), wherein the cones are arranged in multiple rows and the even rows and the odd rows are misaligned with each other. More specifically, one of the rough surfaces of the three adjacent cones 55, 56, and 57 (for example, the rough surfaces 55b, 56b, and 57b) lie in an area 58 defined by the three apexes of the three adjacent cones 55, 56, and 57. Such arrangement helps to reduce defect density and improve epitaxial growth quality.

FIG. 5(b) is another top view of the portion of the patterned substrate 11 for light emitting diode as shown in FIG. 1 according to one embodiment of the present invention. As shown in FIG. 5(b), the patterned substrate 11 comprises a surface 13 having a plurality of cones formed by etching process (for example, the cone 41 as shown in FIG. 4(a)). One of the concave surfaces of the three adjacent cones 51, 52, and 53 (for example, the concave surfaces 51b, 52b, and 53b) lie in an area 54 defined by the three apexes of the three adjacent cones 51, 52, and 53. Such arrangement helps to improve epitaxial growth quality.

One should understand that the cones arrangements as described with reference to FIGS. 5(a) and 5(b) can be applied to other cones disclosed herein (for example the cone 31 as shown in FIGS. 3(a) and 3(b)).

Furthermore, one should understand that the dotted lines as shown in FIGS. 3(a)-5(b) are drawn for purposes of illustrating different regions, not for limiting the disclosed embodiments of the present invention.

FIG. 6 is a scanning electron microscope (SEM) top view of the cone as shown in FIG. 2(a). FIG. 7 is a SEM top view of a portion of a patterned substrate for light emitting diodes.

While the invention has been described in terms of what is presently considered to be the most preferred embodiments and the associated drawings, a person skilled in the art should understand that various modifications, changes, and equivalent alternatives can be made without departing from the spirit and scope of present invention. Other than the methods and apparatus disclosed, there are many alternative ways to execute the present invention. These modifications, changes, and equivalent alternatives fall in the scope of the present invention defined by the appended claims.

What is claimed is:

1. A patterned substrate for light emitting diodes comprising:
a surface having a plurality of cones,
wherein each cones comprises three smooth conical surfaces and three rough surfaces alternatively arranged with respect to each other.

2. The patterned substrate for light emitting diodes of claim 1, wherein each said rough surface comprises an upper portion and a lower portion, wherein each said upper portion has a first base angle ranging from 51 degrees to 70 degrees and each said lower portion has a second base angle ranging from 30 degrees to 50 degrees.

3. The patterned substrate for light emitting diodes of claim 1, wherein the arithmetic mean roughness (Ra) of each said rough surface ranges from 10 nanometer (nm) to 300 nm.

4. The patterned substrate for light emitting diodes of claim 2, wherein the arithmetic mean roughness (Ra) of each said rough surface ranges from 10 nanometer (nm) to 300 nm.

5. The patterned substrate for light emitting diodes of claim 1, wherein the diameter of the base of the cone ranges from 0.2 micron meter (μm) to 5 μm and the height of the cone ranges from 0.1 μm to 2 μm, wherein the ratio of the diameter of the base to the height ranges from 0.02 to 10.

6. The patterned substrate for light emitting diodes of claim 2, wherein the diameter of the base of the cone ranges from 0.2 micron meter (μm) to 5 μm and the height of the cone ranges from 0.1 μm to 2 μm, wherein the ratio of the diameter of the base to the height ranges from 0.02 to 10.

7. The patterned substrate for light emitting diodes of claim 1, wherein when viewed from a top of the cones, one of the rough surfaces of each of three adjacent cones lie in an area defined by the three apexes of the three adjacent cones.

8. The patterned substrate for light emitting diodes of claim 2, wherein when viewed from a top of the cones, one of the rough surfaces of each of three adjacent cones lie in an area defined by the three apexes of the three adjacent cones.

9. A patterned substrate for light emitting diodes, comprising:
a surface having a plurality of cones,
wherein each cones includes three smooth conical surfaces and three concave surfaces alternatively arranged with respect to each other, wherein each said concave surface comprises an upper portion and a lower portion, wherein each said upper portion has a first base angle ranging from 51 degrees to 70 degrees and each said lower portion has a second base angle ranging from 30 degrees to 50 degrees.

10. The patterned substrate for light emitting diodes of claim 9, wherein the diameter of the base of the cone ranges from 0.2 μm to 5 μm and the height of the cone ranges from 0.1 μm to 2 μm, wherein the ratio of the diameter of the base to the height ranges from 0.02 to 10.

11. The patterned substrate for light emitting diodes of claim 9, wherein when viewed from a top of the cones, one of the concave surfaces of each of three adjacent cones lie in an area defined by the three apexes of the three adjacent cones.
